(19) United States
(12) Patent Application Publication
(10) Pub. No.: US 2005/0221591 A1
(43) Pub. Date: Oct. 6, 2005

(54) Method of forming high-quality relaxed SiGe alloy layers on bulk Si substrates

(75) Inventors: Stephen W. Bedell, Wappingers Falls, NY (US); Huajie Chen, Wappingers Falls, NY (US); Joel P. de Souza, Putnam Valley, NY (US); Keith E. Fogel, Mohegan Lake, NY (US); Devendra K. Sadana, Pleasantville, NY (US); Ghavam G. Shahidi, Pound Ridge, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, ARMONK, NY (US)

(21) Appl. No.: 10/818,572

(22) Filed: Apr. 6, 2004

(51) Int. Cl. H01L 31/0328; H01L 21/36; H01L 21/20; C30B 1/00; H01L 31/109; H01L 31/072; H01L 31/0336

(52) U.S. Cl. 438/479

(57) ABSTRACT

A method of forming a high-quality relaxed SiGe alloy layer on a bulk Si-containing substrate is provided. The method of the present invention includes growing a strained SiGe alloy layer on a Si-containing substrate that has a porous Si-containing layer at or near the surface of the Si-containing substrate. The porous layer is formed by an electrolytic anodization process. The pores create free volume below the strained SiGe layer which can serve to accommodate strain relaxation during SiGe deposition or a subsequent heating step. The subsequent heating step is optional and is performed to further increase the relaxation of the SiGe alloy layer. The buried porous structure allows for a unique relaxation mechanism compared to prior art methods.

### FIELD OF THE INVENTION

The present invention relates to a method of fabricating a semiconductor structure, and more particularly to a method of forming a semiconductor structure in which a high-quality relaxed silicon germanium (SiGe) alloy layer is formed atop a bulk Si-containing substrate.

### BACKGROUND OF THE INVENTION

Charge carriers in tensile strained Si layers have a higher mobility compared to carriers in unstrained Si layers. This has resulted in an effort to produce thin strained Si layers for use in future high-performance complementary metal oxide semiconductor (CMOS) devices. The increased mobility of the charge carriers in these materials translates into higher current drive and thus higher operating frequency transistors.

In most prior art methods, a thin Si layer under tensile strain is formed by growing the Si layer on a relaxed SiGe alloy layer. The ongoing challenge in the development of strained-Si substrates is to achieve high strain relaxation of the SiGe layer while simultaneously minimizing the dislocation defect density. Because the dislocations are ultimately responsible for the strain relaxation of the SiGe layer, most prior art methods have focused on burying the dislocations below the surface once the relaxation is sufficiently high. See, for example, E. A. Fitzgerald, Y. H. Xie, M. L. Green, D. Brasen, A. R. Kortan, J. Michel, Y. J. Mii and B. E. Weir, Appl. Phys. Lett., 59, (1991) 811.

Other prior art methods have addressed the defect issue by growing metastable, defect-free, SiGe layers followed by the creation of a buried damage layer near the SiGe/Si substrate interface and subsequent thermal treatment to relax the SiGe. See, for example, H. Trinkaus, B. Hollander, St. Rongen, S. Mantl, H.-J. Herzog, J. Kuchenbecker and T. Hackbarth, Appl. Phys. Lett., 76, (2000) 3552. In this manner, the buried defects act as dislocation nucleation sources and a large number of the dislocation loops remain pinned at the buried interface thereby reducing the number of dislocations that extend to the surface.

It is possible to create highly relaxed SiGe layers of reasonable crystal quality using either of the two aforementioned approaches. The problem with both prior art methods is twofold 1) the amount of relaxation is directly related to how thick the SiGe layers are and 2) the large processing cost to produce these wafers (by either method) creates a large barrier to industrial acceptance. Items 1) and 2) mentioned above are somewhat related in that if high relaxation is desired (and usually is), much thicker SiGe layers must be grown; adding to the cost of the substrate.

In view of the above drawbacks with the prior art methods, a new and improved method of forming a highly-relaxed SiGe layer, with a high crystalline quality, in an inexpensive and manufacturable manner, is needed.

### SUMMARY OF THE INVENTION

The present invention provides a method for fabricating highly relaxed, low defect, single crystalline SiGe alloy layers. The term “highly relaxed” is used throughout the present application to denote a SiGe alloy layer that has a measured degree of relaxation of about 50% or higher. The term “low defect” is used throughout the present application to denote a SiGe alloy layer that has a defect density of about 10⁷ cm⁻² or less. The low defect density of the resultant SiGe alloy layer provides a high quality film for forming a strained Si-containing layer thereon.

In accordance with the method of the present invention, a strained SiGe alloy layer is grown on a Si-containing substrate that has a porous Si-containing layer at or near the surface of the Si-containing substrate. The pores create free volume below the strained SiGe layer which can assist strain relaxation during growth and also during a subsequent heating step. The buried porous structure allows for a unique relaxation mechanism compared to prior art methods.

In broad terms, the method of the present invention comprises the steps of:
forming a porous Si-containing layer at, or near, a surface of a Si-containing substrate; and
growing a relaxed SiGe alloy layer on top of said surface of said Si-containing substrate containing said porous Si-containing layer.

Optionally, a step of thermally treating the Si-containing substrate containing the porous Si-containing layer and the SiGe alloy layer to increase relaxation of the SiGe alloy layer can be performed.

An optional Si-containing layer or a SiGe/Si layer can be grown on top of the relaxed SiGe alloy layer.

### BRIEF DESCRIPTION OF THE DRAWINGS

FIGS. 1A-1E are pictorial representations (through cross sectional views) illustrating the basic processing steps that can be employed in the present invention.

FIG. 2 is a SEM of a structure which includes a substantially relaxed SiGe alloy layer formed atop a bulk Si-containing substrate utilizing the method of the present invention. A 5 minute hydrogen bake step at 1100° C. was performed prior to SiGe alloy layer deposition to form a continuous Si-containing layer over the porous structure. Relaxation of the SiGe layer was performed in a subsequent heating step in an inert ambient.

FIG. 3 is a XTEM of a structure which includes a substantially relaxed SiGe alloy layer formed atop a bulk Si-containing substrate utilizing the method of the present invention. A 1 minute hydrogen bake step at 1100° C. was performed prior to SiGe alloy layer deposition to form a continuous Si-containing layer over the porous structure. Relaxation of the SiGe layer was performed in a subsequent heating step in an oxidizing ambient.

### DETAILED DESCRIPTION OF THE INVENTION

The present invention, which provides a method of forming a high-quality relaxed SiGe alloy layer on a bulk Si-containing substrate, will now be described in greater detail by referring to the drawings that accompany the present application.

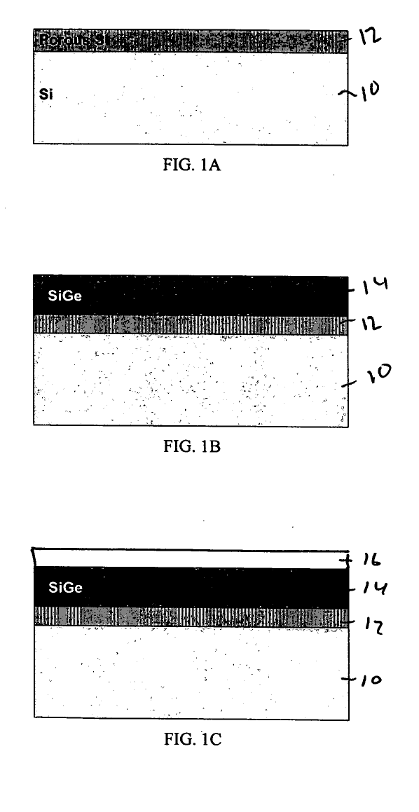

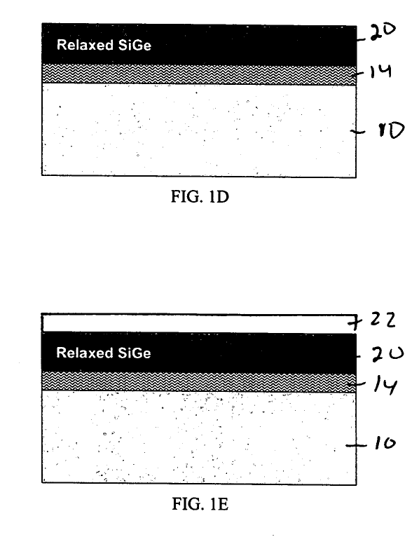

Reference is first made to FIGS. 1A-1E which illustrate the basic processing steps that are employed in the present invention. FIG. 1A shows a structure during the initial stage of the present invention in which a porous Si-containing layer 12 is formed at, or near, a surface layer of a bulk Si-containing substrate 10.

The term “Si-containing” is used throughout the present application to denote a semiconductor material that includes at least silicon. Illustrative examples of such Si-containing materials include, but are not limited to: Si, SiGe, SiC, SiGeC, Si/Si, Si/SiC, and Si/SiGeC. The bulk Si-containing substrate 10 used in the present invention may be undoped or it may be an electron-rich or hole-rich Si-containing substrate. The bulk Si-containing substrate 10 can have any crystallographic orientation including, for example, <100>, <110> or <111>.

The porous Si-containing layer 12 is formed within a surface region of the Si-containing substrate 10 by utilizing an electrolytic anodization process that is capable of forming a porous region within the substrate.

The anodization process is performed by immersing the Si-containing substrate 10 into an HF-containing solution while an electrical bias is applied to the substrate with respect to an electrode also placed in the HF-containing solution. In such a process, the substrate typically serves as the positive electrode of the electrochemical cell, while another semiconducting material such as Si, or a metal is employed as the negative electrode.

In general, the HF anodization converts single crystal Si into porous Si. The rate of formation and the nature of the porous Si so-formed (porosity and microstructure) is determined by both the material properties, i.e., doping type and concentration, as well as the reaction conditions of the anodization process itself (current density, bias, illumination and additives in the HF-containing solution).

Generally, the porous Si-containing layer 12 formed in the present invention has a porosity of about 0.1% or higher. The depth of the porous Si-containing layer 12, as measured from the uppermost surface of the substrate to the uppermost surface of the porous Si-containing layer 12, is about 50 nm or less. Hence, within the recited ranges the porous Si-containing layer 12 is formed at, or near, the surface of Si-containing substrate 10.

The term “HF-containing solution” includes concentrated HF (49%), a mixture of HF and water, a mixture of HF and a monohydric alcohol such as methanol, ethanol, propanol, etc, or HF mixed with at least one surfactant. The surfactant includes conventional materials well-known in the art. The amount of surfactant that is present in the HF solution is typically from about 1 to about 50%, based on 49% HF.

The anodization process is performed using a current source that operates at a current density from about 0.05 to about 50 milliamps/cm². A light source may be optionally used to illuminate the sample. More preferably, the anodization process of the present invention is employed using a constant current source operating at a current density from about 0.1 to about 50 milliamps/cm².

The anodization process is typically performed at room temperature or, alternatively a temperature that is below room temperature may be used. Following the anodization process, the structure is typically rinsed with deionized water and dried.

After providing the structure shown in FIG. 1A, a strained SiGe alloy layer 14 is formed atop the structure. The resultant structure including the SiGe alloy layer 14 atop the Si-containing substrate 10 which includes a surface porous Si-containing layer 12 is show, for example, in FIG. 1B.

In some embodiments of the present, the structure is subjected to a hydrogen baking step prior to the formation of the SiGe alloy layer. When the hydrogen baking step is employed, the structure is typically heated in a hydrogen-containing ambient at a temperature from about 800° to about 1200° C., with a temperature from about 900° to about 1150° C. being more typical. The hydrogen baking step is performed on the structure for a time period that is about 1 min or greater.

The term “SiGe alloy layer” denotes a material that includes up to 99.99 atomic percent Ge. Typically, the Ge content in the SiGe alloy is from about 0.1 to about 99.9 atomic percent, with a Ge atomic percent of from about 10 to about 35 atomic percent being even more typical.

In accordance with the present invention, the SiGe alloy layer 14 is formed atop the upper surface of Si-containing substrate 10 containing the porous Si-containing layer 12 using any conventional epitaxial growth method that is known to those skilled in the art which is capable of growing a strained SiGe layer. It is noted that immediately after growth, the SiGe alloy layer 14 will have some degree of relaxation associated therewith.

Illustrative examples of such epitaxial growing processes that can be used in the present invention include, but are not limited to: low-pressure chemical vapor deposition (LPCVD), rapid thermal chemical vapor deposition (RTCVD), low-energy plasma deposition (LEPD), ultra-high vacuum chemical vapor deposition (UHVCVD), atmospheric pressure chemical vapor deposition (APCVD), molecular beam epitaxy (MBE) and plasma-enhanced chemical vapor deposition (PECVD).

The thickness of the SiGe alloy layer 14 formed at this point of the present invention may vary, but typically SiGe alloy layer 14 has a thickness from about 10 to about 500 nm, with a thickness from about 20 to about 200 nm being more highly preferred.

In an optional embodiment, as shown in FIG. 1C, an optional cap layer 16 is formed atop the structure including the SiGe alloy layer 14. The optional cap layer 16 employed in the present invention comprises any Si-containing material including, for example, epitaxial Si (epi-Si), amorphous Si (a: Si), single or polycrystalline Si or any combination thereof. Of the various Si-containing materials listed above, it is preferred that epi-Si be employed as the optional cap layer 16.

When present, the optional cap layer 16 has a thickness from about 1 to about 100 nm, with a thickness from about 1 to about 30 nm being more highly preferred. The optional cap layer 16 is formed using known deposition processes including one of the epitaxial growth processes mentioned above.

The structure including the SiGe alloy 14, with or without the optional cap layer 16, (see, FIG. 1B or FIG. 1C) is then heated, i.e., annealed, at a temperature which permits the further relaxation of the SiGe alloy layer 14 into a substantially relaxed SiGe alloy layer 20. The heating step is optional, thus it does not need to be performed in all instances. A two-fold or greater improvement in relaxation can be obtained in some preferred embodiments of the present invention when the optional heating step is performed. Although the heating step is optional, it is advantageous to employ the same to increase the relaxation of the SiGe alloy layer. The resultant structure is shown, for example, in FIG. 1D. That is, the heating step forms a further relaxed single crystal SiGe layer 20 atop the bulk substrate. Note that a surface oxide layer (not shown) can be formed atop layer 20 during the heating step when oxygen-containing ambients are employed. This surface oxide layer is typically, but not always, removed from the structure after the heating step using a conventional wet etch process wherein a chemical etchant such as HF that has a high selectivity for removing oxide as compared to SiGe is employed.

Specifically, the heating step of the present invention is an annealing step which is performed at a temperature from about 500° to about 1350° C., with a temperature from about 900° C. to at or near the alloy melting point temperature being more highly preferred. Moreover, the heating step of the present invention is carried out in an inert ambient such as He, Ar, N₂, Xe, Kr, Ne or mixtures thereof, an oxidizing ambient which includes at least one oxygen-containing gas such as O₂, NO, N₂O, ozone, air and other like oxygen-containing gases, and mixtures of oxygen-containing gases and inert gases. When such an admixture is employed, the diluted ambient contains from about 0.5 to about 100% of oxygen-containing gas, the remainder, up to 100%, being inert gas.

The heating step may be carried out for a variable period of time that typically ranges from about 10 to about 1800 minutes, with a time period from about 60 to about 600 minutes being more highly preferred. The heating step may be carried out at a single targeted temperature, or various ramp and soak cycles using various ramp rates and soak times can be employed. The use of rapid thermal annealing (RTA), laser annealing and other energy sources such as electron beams are also contemplated herein as possible alternatives to perform the said heating step.

In accordance with the present invention, substantially relaxed SiGe layer 20 has a thickness of about 2000 nm or less, with a thickness from about 10 to about 100 nm being more highly preferred. Note that the substantially relaxed SiGe layer 20 formed in the present invention is thinner than prior art SiGe buffer layers and has a defect density of threading dislocations, of less than about 10⁷ defects/cm². The substantially relaxed SiGe layer 20 formed in the present invention has a final Ge content from about 0.1 to about 99.9 atomic percent, with an atomic percent of Ge from about 10 to about 35 being more highly preferred. Another characteristic feature of the substantially relaxed SiGe layer 20 is that it has a measured lattice relaxation from about 1 to about 100%, with a measured lattice relaxation from about 50 to about 100% being more highly preferred.

At this point of the present invention, a Si-containing layer or a SiGe/Si layer can be formed atop the substantially relaxed SiGe alloy layer 20. FIG. 1E shows a structure in which the optional Si-containing layer or SiGe/Si layer is formed atop layer 20. In the drawing, reference 22 is used to denote the optional layer. Optional layer 22 may be formed utilizing a conventional epitaxial growing method(s) that is well known to those skilled in the art. The optional layer 22 typically has a thickness from about 1 to about 50 nm, with a thickness from about 5 to about 30 nm being more typical.

In some embodiments, the above processing steps of anodization, formation of a SiGe alloy layer and thermal annealing to relax the SiGe alloy layer may be repeated any number of times.

It is also contemplated herein that growth of the SiGe alloy layer be performed using Ge and/or Si sources that are isotopically enriched in order to improve the thermal conductivity of the SiGe alloy layer. For example, growing the SiGe alloy layer wherein greater than 37% of the Ge atoms have a mass of 74 amu (atomic mass unit) and greater than 93% of the Si atoms have a mass of 28 amu, is isotopically enriched and will have a higher thermal conductivity than the same alloy with an atomic mass distribution corresponding to the natural abundance. It is preferred that the abovementioned percentages are as close to 100% as possible.

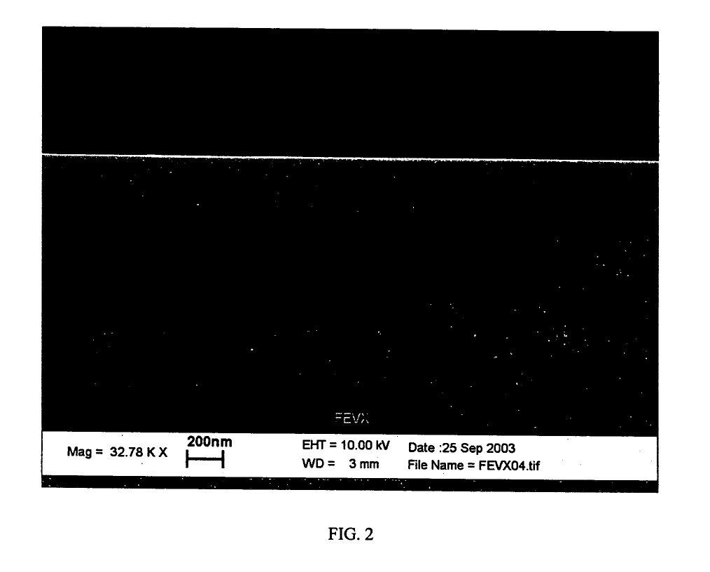

FIG. 2 is a SEM of a structure that includes a substantially relaxed SiGe alloy layer formed atop a bulk Si-containing substrate utilizing the method of the present invention. A hydrogen bake step for 5 minutes at 1100° C. was performed to create a continuous Si-containing layer over the porous structure and deposition of a 100 nm thick Si_{0.8}Ge_{0.2} layer was performed thereafter at 650° C. in the same RTCVD chamber. Immediately after growth, the SiGe layer was already about 40% relaxed. A subsequent heating step at 1000° C. in an inert ambient was performed to increase the relaxation to about 85%.

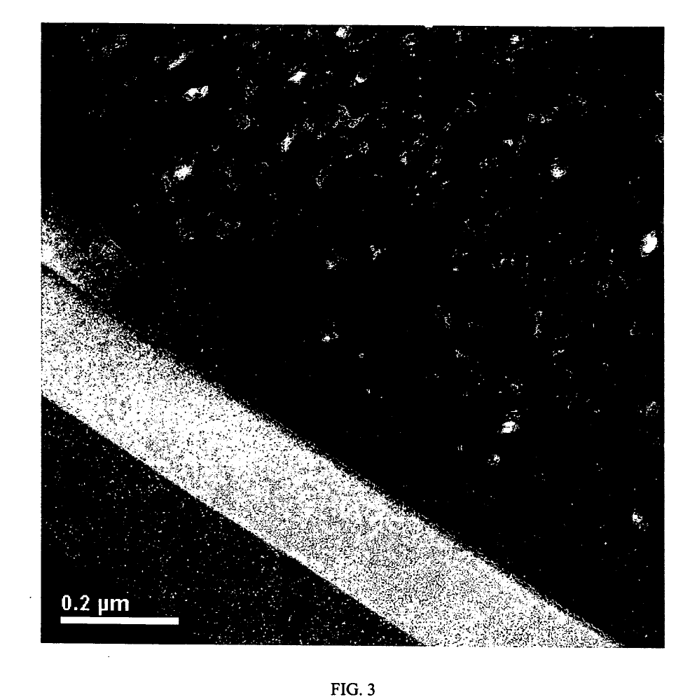

FIG. 3 is a XTEM of a structure which includes a substantially relaxed SiGe alloy layer formed atop a bulk Si-containing substrate utilizing the method of the present invention. A hydrogen bake step for 1 minute at 1100° C. was performed to create a continuous Si-containing layer over the porous structure and deposition of a 150 nm thick Si_{0.8}Ge_{0.2} layer was performed thereafter at 650° C. in the same RTCVD chamber. A heating step was then performed in an oxidizing ambient at 1200° C. for 30 minutes. In this XTEM, the grainy region is the porous Si-containing layer 12, the layer adjacent to the porous Si-containing layer is the highly relaxed, high-quality SiGe alloy layer, and the bright layer adjacent to the relaxed SiGe alloy layer is the surface oxide resulting from the oxidation step.

In the embodiment described and illustrated above, an unpatterned structure is formed. In another embodiment, a patterned structure is formed by first providing a patterned mask or photoresist (not shown) atop the Si-containing substrate 10. This providing step occurs prior to formation of the porous region. The patterned mask can be formed by deposition, lithography and optionally etching. Ion implantation of the masked wafer to introduce p-type dopants (e.g., boron) will result in the selective formation of porous regions where implantation occurred during subsequent HF anodization. A patterned porous region is then formed in the portion of the Si-containing substrate that did not include the patterned mask. The various steps of porous layer formation, SiGe alloy formation and thermal treatment include all features and embodiments already described herein above. When patterning is employed, the final structure would like similar to FIG. 1D, but for the exception that layer 14 and layer 20 do not extend entirely across the surface of the structure.

In the embodiment described and illustrated above, the Si-containing substrate 10 is typically a Si substrate. In another embodiment, the Si-containing substrate 10 is an existing SiGe (pseudomorphic or partially relaxed) layer atop a Si substrate. Boron, or another p-type dopant can be incorporated into the existing SiGe layer either during growth of the SiGe layer or by a post-growth ion implantation process. The same steps are described above can be carried out to form a porous region which includes a portion or the entirety of the SiGe alloy surface layer of the Si-containing substrate.

While the present invention has been particularly shown and described with respect to preferred embodiments thereof, it will be understood by those skilled in the art that the foregoing and other changes in forms and details may be made without departing from the scope and spirit of the present invention. It is therefore intended that the present invention not be limited to the exact forms and details described and illustrated, but fall within the scope of the appended claims.

1. A method of forming a semiconductor structure comprising the steps of:
forming a porous Si-containing layer at, or near, a surface of a Si-containing substrate; and
growing a relaxed SiGe alloy layer on top of said surface of said Si-containing substrate containing said porous Si-containing layer.

2. The method of claim 1 further comprising thermally treating the Si-containing substrate containing the porous Si-containing layer and the relaxed SiGe alloy layer to cause further relaxation of the SiGe alloy layer

3. The method of claim 1 wherein the porous Si-containing layer is formed by an electrolytic anodization process.

4. The method of claim 3 wherein the electrolytic anodization process is performed in a HF-containing solution.

5. The method of claim 4 wherein the HF-containing solution further comprises a surfactant.

6. The method of claim 4 wherein the HF-containing solution comprises concentrated HF (49%).

7. The method of claim 4 wherein the HF-containing solution further comprises water.

8. The method of claim 4 wherein the HF-containing solution further comprises a monohydric alcohol.

9. The method of claim 3 wherein the electrolytic anodization process is performed using a current source operating at a current density from about 0.005 to 50 milliamps/cm².

10. The method of claim 1 wherein the Si-containing porous layer has a porosity of about 0.1% or greater.

11. The method of claim 1 wherein the Si-containing porous layer is formed at a depth of less than 50 nm from the surface of the Si-containing substrate.

12. The method of claim 1 wherein the SiGe alloy layer is formed by an epitaxial growth process.

13. The method of claim 2 wherein the thermally treating step is performed at a temperature from about 500° to about 1350° C.

14. The method of claim 12 wherein the thermally treating step is performed at a temperature that is at, or below, the melting point of the SiGe alloy layer.

15. The method of claim 2 wherein the thermally treating step is carried out in an inert ambient, an oxidizing ambient or a mixture of an oxygen-containing ambient and an inert ambient.

16. The method of claim 2 wherein the thermally treating step is performed in an oxidizing ambient.

17. The method of claim 2 wherein the thermally treating step is performed using rapid thermal annealing.

18. The method of claim 1 further comprising subjecting the Si-containing substrate containing said porous Si-containing layer to a hydrogen bake step prior to forming said SiGe alloy layer.

19. The method of claim 1 further comprising forming a Si-containing layer on said relaxed SiGe alloy layer.

20. The method of claim 1 further comprising forming a SiGe/Si layer on said relaxed SiGe alloy layer, wherein said Si is formed on a surface of the relaxed SiGe alloy layer and said SiGe is formed on a surface of the Si layer.

21. The method of claim 1 wherein the Si-containing substrate has a crystallographic orientation that is either <100>, <110>, or <111>.

22. The method of claim 1 wherein growth of the said SiGe alloy layer is performed using isotopically enriched Ge and/or Si sources.

23. The method of claim 1 wherein a patterned mask is formed on said Si-containing substrate prior to said forming said porous Si-containing layer.

24. The method of claim 1 wherein said Si-containing substrate comprises an existing SiGe alloy layer formed atop a Si substrate.

25. The method of claim 24 wherein the existing SiGe alloy layer is doped with a p-type dopant prior to forming said porous Si-containing layer.

26. A method of forming a semiconductor structure comprising the steps of:
forming a porous Si-containing layer at, or near, a surface of a Si-containing substrate;
growing a SiGe alloy layer on top of said surface of said Si-containing substrate containing said porous Si-containing layer; and
thermally treating the Si-containing substrate containing the porous Si-containing layer and the SiGe alloy layer to cause further relaxation of the SiGe alloy layer.
